(19) United States
(12) Patent Application Publication
(10) Pub. No.: US 2015/0100262 A1
(43) Pub. Date: Apr. 9, 2015

(54) Method and System for Constructing Map of Magnetic Field

(71) Applicant: IDECCA INC., Seoul (KR)

(72) Inventor: Chan Jong Park, Seoul (KR)

(73) Assignee: IDECCA INC., Seoul (KR)

(21) Appl. No.: 14/151,669

(22) Filed: Jan. 9, 2014

(30) Foreign Application Priority Data
Oct. 7, 2013 (KR) 10-2013-0119122

(51) Int. Cl. G01R 33/02; G01R 13/00

(52) U.S. Cl. CPC G01R 33/02; G01R 13/00
USPC 702/65

(57) ABSTRACT

A method for constructing a map of a magnetic field includes acquiring the map information including the information on the internal or external structure of the building; measuring the information on the magnetic field, using the measurer's electronic device; and associating the information on the magnetic field with the map information based on the schedule information, wherein the schedule information is generated based on the structure information or a command made by the measurer.

### CROSS REFERENCE TO RELATED APPLICATION

This application claims priority from and the benefit of Korean Patent Application No. 10-2013-0119122, filed on Oct. 7, 2013, which is hereby incorporated by reference for all purposes as if fully set forth herein.

### BACKGROUND OF THE DISCLOSURE

1. Field of the Disclosure

Exemplary embodiments of the disclosure relate to a method and a system for constructing a map of a magnetic field, more particularly, to a technology for constructing a map of a magnetic field by measuring an internal or external magnetic field of a building.

2. Discussion of the Background

Generally, technology for constructing a map to position a user's terminal uses information on an internal or external structure of a building and such technology constructs the map, using information on coordinates provided in the structure information.

However, the map constructed only using the coordinate's information has a disadvantage of failure in providing accurate information on a vertical location of a user terminal.

Accordingly, methods and systems for constructing a map for positioning the user's terminal accurately are required.

The above information disclosed in this Background section is only for enhancement of understanding of the background of the disclosed subject matter and therefore may contain information that does not form any part of the prior art nor what the prior art may suggest to a person of ordinary skill in the art.

### SUMMARY OF THE DISCLOSURE

Exemplary embodiments of the present disclosure provide a method and a system for constructing a map of a magnetic field used in positioning a user's terminal.

Exemplary embodiments of the present disclosure also provide a method and a system for relating information on the measured magnetic field to map information based on schedule information in a process for constructing a map of a magnetic field.

Exemplary embodiments of the present disclosure also provide a method and a system for managing a measuring electronic device, while a measurer's electronic device is measuring a magnetic field.

Exemplary embodiments of the present disclosure also provide a method and a system for providing specific services associated with a location of a user's terminal based on a map of a magnetic field.

Additional features of the present disclosure will be set forth in the description which follows, and in part will be apparent from the description, or may be learned by practice of the disclosed subject matter.

Exemplary embodiments of the present disclosure disclose a method for constructing a map of a magnetic field including acquiring the map information including the information on the internal or external structure of the building; measuring the information on the magnetic field, using the measurer's electronic device; and associating the information on the magnetic field with the map information based on the schedule information, wherein the schedule information is generated based on the structure information or a command made by the measurer.

The schedule information may include information on a moving route, a moving direction, a moving speed or a height from the ground of the measurer's electronic device.

The measurer's electronic device may measure a horizontal value and a vertical value of the magnetic field corresponding to the structure information, using a magnetic field sensor provided in the measurer's electronic device.

The method of constructing the map of the magnetic field may further include providing a specific service associated with a location of a user terminal based on the information on the associated magnetic fields and the map information.

The providing the specific service may include acquiring the location of the user terminal by mapping the magnetic field measured by the magnetic field sensor provided in the user terminal with the information on the associated magnetic fields and the map information; and providing the specific service through an application installed in the user terminal based on the acquired location of the user terminal.

The method of constructing the map of the magnetic field may further include downloading the information on the associated magnetic fields and the map information to the user terminal.

The method of constructing the map of the magnetic field may further include transmitting schedule information for measuring a magnetic field inside or outside the building based on the structure information.

Exemplary embodiments of the disclosure also disclose a method of constructing a map of a magnetic field including acquiring map information comprising structure information inside or outside a building; measuring information on a magnetic field inside or outside the building, using a measurer's electronic device; and associating the information on the magnetic field with the map information based on the schedule information or transmitting the information on the magnetic field to a system for constructing a map of a magnetic field, wherein the schedule information is generated based on the structure information or based on the measurer's command.

The method of constructing the map of the magnetic field may further include monitoring a measuring state of the electronic device, while the measurer's electronic device is measuring the magnetic field inside or outside the building; and providing an alarm to the measurer's electronic device based on the measuring state of the electronic device and the schedule information.

Exemplary embodiments of the disclosure also disclose a system for constructing a map of a magnetic field including an acquiring unit for acquiring map information comprising information on an internal or external structure of a building; a receiving unit for receiving information on a magnetic field measured inside or outside the building from the measurer's electronic device; and an associating unit for associating the information on the magnetic field and the map information with each other based on the schedule information, wherein the schedule information is generated based on the structure information or based on a command input by the measurer.

According to the exemplary embodiments of the disclosure, exemplary embodiments of the present disclosure provide a method and a system for constructing a map of a magnetic field used in positioning a user's terminal.

Furthermore, exemplary embodiments of the present disclosure also provide a method and a system for relating information on the measured magnetic field to map information based on schedule information in a process for constructing a map of a magnetic field.

Still further, exemplary embodiments of the present disclosure also provide a method and a system for managing an electronic device possessed by a measurer, while a measurer's electronic device is measuring a magnetic field.

Still further, exemplary embodiments of the present disclosure also provide a method and a system for providing specific services associated with a location of a user's terminal based on a map of a magnetic field.

It is to be understood that both the foregoing general description and the following detailed description are exemplary and explanatory and are intended to provide further explanation of the disclosed subject matter as claimed.

### BRIEF DESCRIPTION OF THE DRAWINGS

The accompanying drawings, which are included to provide a further understanding of the disclosed subject matter and are incorporated in and constitute a part of this specification, illustrate exemplary embodiments of the disclosed subject matter, and together with the description serve to explain the principles of the disclosed subject matter.

FIG. 1 is a diagram illustrating map information according to exemplary embodiments of the disclosure;

FIG. 2 is a diagram illustrating a screen of an electronic device possessed by a measurer according to exemplary embodiments of the disclosure;

FIG. 3 is a diagram illustrating a map of a magnetic field according to exemplary embodiments of the disclosure;

FIG. 4 is a diagram illustrating a map of a magnetic field based on a height according to exemplary embodiments of the disclosure;

FIG. 5 is a diagram illustrating a process of positioning a user's terminal according to exemplary embodiments of the disclosure;

FIG. 6 is a diagram illustrating a screen of a user's terminal which displaying a specific service according to exemplary embodiments of the disclosure;

FIG. 7 is a flow chart illustrating a method for constructing a magnetic field according to exemplary embodiments of the disclosure; and

FIG. 8 is a block diagram illustrating a system for constructing a magnetic map according to exemplary embodiments of the disclosure.

### DETAILED DESCRIPTION OF THE ILLUSTRATED EMBODIMENTS

Exemplary embodiments of the disclosed subject matter are described more fully hereinafter with reference to the accompanying drawings. The disclosed subject matter may, however, be embodied in many different forms and should not be construed as limited to the exemplary embodiments set forth herein. Rather, the exemplary embodiments are provided so that this disclosure is thorough and complete, and will convey the scope of the disclosed subject matter to those skilled in the art. In the drawings, the size and relative sizes of layers and regions may be exaggerated for clarity. Like reference numerals in the drawings denote like elements.

It will be understood that when an element or layer is referred to as being “on”, “connected to”, or “coupled to” another element or layer, it can be directly on, connected, or coupled to the other element or layer or intervening elements or layers may be present. In contrast, when an element is referred to as being “directly on”, “directly connected to”, or “directly coupled to” another element or layer, there are no intervening elements or layers present. As used herein, the term “and/or” includes any and all combinations of one or more of the associated listed items. It may also be understood that for the purposes of this disclosure, “at least one of X, Y, and Z” can be construed as X only, Y only, Z only, or any combination of two or more items X, Y, and Z (e.g., XYZ, XYY, YZ, ZZ).

It will be understood that, although the terms first, second, third etc. may be used herein to describe various elements, components, regions, layers, and/or sections, these elements, components, regions, layers, and/or sections should not be limited by these terms. These terms are only used to distinguish one element, component, region, layer, or section from another region, layer or section. Thus, a first element, component, region, layer, or section discussed below could be termed a second element, component, region, layer, or section without departing from the teachings of the present disclosure.

The terminology used herein is for the purpose of describing exemplary embodiments only and is not intended to be limiting of the disclosed subject matter. As used herein, the singular forms “a”, “an”, and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Exemplary embodiments of the disclosed subject matter are described herein with reference to cross-section illustrations that are schematic illustrations of idealized embodiments (and intermediate structures) of the disclosed subject matter. As such, variations from the shapes of the illustrations as a result, for example, of manufacturing techniques and/or tolerances, are to be expected. Thus, exemplary embodiments of the disclosed subject matter should not be construed as limited to the particular shapes of regions illustrated herein but are to include deviations in shapes that result, for example, from manufacturing.

Unless otherwise defined, all terms (including technical and scientific terms) used herein have the same meaning as commonly understood by one of ordinary skill in the art to which this disclosed subject matter belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, exemplary embodiments of the disclosed subject matter will be described in detail with reference to the accompanying drawings.

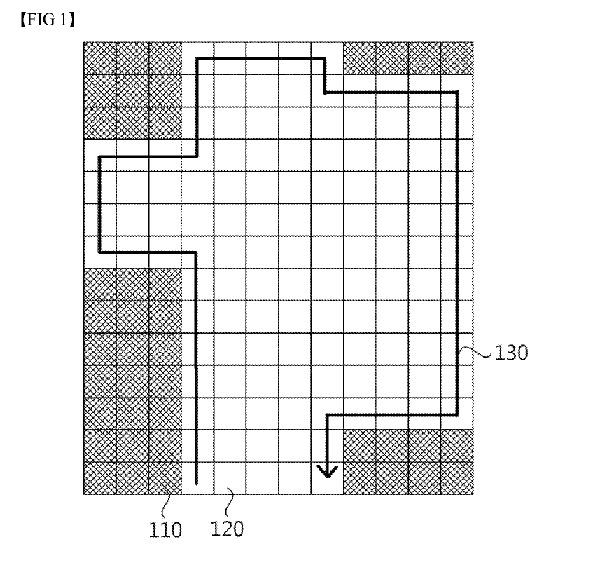

FIG. 1 is a diagram illustrating map information according to the exemplary embodiments of the disclosure.

Referring to FIG. 1, the map information according to the exemplary embodiments of the disclosure includes information on an internal or external structure of a building which is an object of map information. The structure information may be defined based on information on preset coordinates. For example, the map information may include a plurality of cells corresponding to the preset coordinates information and information on structures of a wall 110 and a passage 120. Specifically, the map information may include coordinates information (3.0) and (5.0). The map information may include the structure information that shows that the coordinate of (3.0) is corresponding to the wall 110 and the coordinate information of (5.0) is corresponding to the passage 120, using light and shade.

A system for constructing a magnetic field (that is, a server for constructing a magnetic field and providing a magnetic field-based location service) may acquire map information to construct the magnetic map. Also, the system may transmit schedule information for measuring a magnetic field inside or outside a building based on the acquired map information to an electronic device possessed by a measurer. The schedule information may be generated not by the system for constructing the magnetic field but by a command of the measurer who has the electronic device. The electronic device may be a mobile device including a processor, a memory, a communication interface, a display and a user interface.

Here, the schedule information may include information on a moving path, a moving direction and a moving speed or height of the electronic device possessed by the measurer so as to construct the magnetic field. For example, when constructing a magnetic field in the building having structure information on a wall 110 and a passage 120, schedule information may include information on a moving route 130 of an electronic device possessed by a measurer and on a moving speed of km/h and on a height of 1 m. The system for constructing the magnetic field transmits such the schedule information to the electronic device possessed by the measurer, such that the measurer's electronic device can measure a magnetic field, after moving at a speed of 4 km by a height of 1 m from the ground along the moving route 130. In addition, the measurer of the electronic device may set schedule information on the moving route, the moving speed and the moving height manually.

The system for constructing the magnetic field and the electronic device may share the schedule information generated by the electronic device or the schedule information generated by the system for constructing the magnetic field with each other.

In this instance, the electronic device possessed by the measurer may include a magnetic field sensor to measure a horizontal value and a vertical value of a magnetic field corresponding to the structure information.

Also, the electronic device having a system or an application for constructing the magnetic field may monitor a state of the electronic device measuring the magnetic field, which measuring a magnetic field inside or outside the building, and provide an alarm based on the measurement state and the schedule information of the electronic device possessed by the measurer.

For example, when a location of the electronic device possessed by a measurer is out of the passage 130, the electronic device having the system or application for constructing the map of the magnetic field provided therein may notice that the electronic device is out of the preset passage 1303 based on the schedule information set by the measurer. The location of the electronic device possessed by the measurer may be identified by another sensor distinguished from the magnetic field sensor provided in the measurer's electronic device. For example, the measurer's electronic device may measure the location, using one or more of an acceleration sensor, an inertial sensor, a gyro sensor, a pressure sensor, an ultrasonic sensor, and a temperature-humidity sensor, an infrared sensor, a sensor for detecting UWB (Ultra-Wideband) and Wi-Fi (Wireless Fidelity) and a sensor for detecting LED (Light Emitting Diode). The electronic device may transmit the measured location thereof to a system for constructing a magnetic map. The system for constructing the map of the magnetic field may acquire the location of the electronic device and determines whether the electronic device measures the magnetic field based on the schedule information.

The system for constructing the map of the magnetic field receives information on the magnetic field measured inside or outside the corresponding building from the electronic device possessed by the measurer and associates the information on the magnetic field with the map information, such that the system can construct the map of the magnetic field. For example, the system for constructing the map of the magnetic field may map the received information on the magnetic field with the map information based on one or more of a moving route, a moving direction and a moving speed or height of the electronic device, so as to associate the information on the magnetic field with the map information. At this time, the system for constructing the map of the magnetic field may map the information on the magnetic field with corresponding preset coordinate information provided in the map information. Hereinafter, the magnetic field means the associated information of the magnetic field information and the map information.

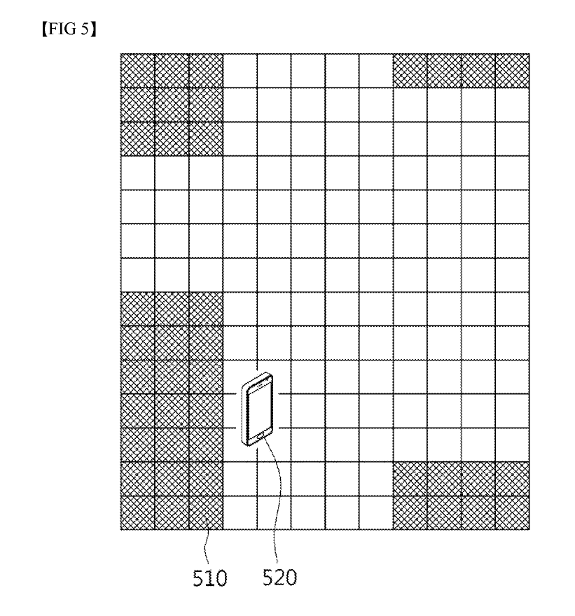

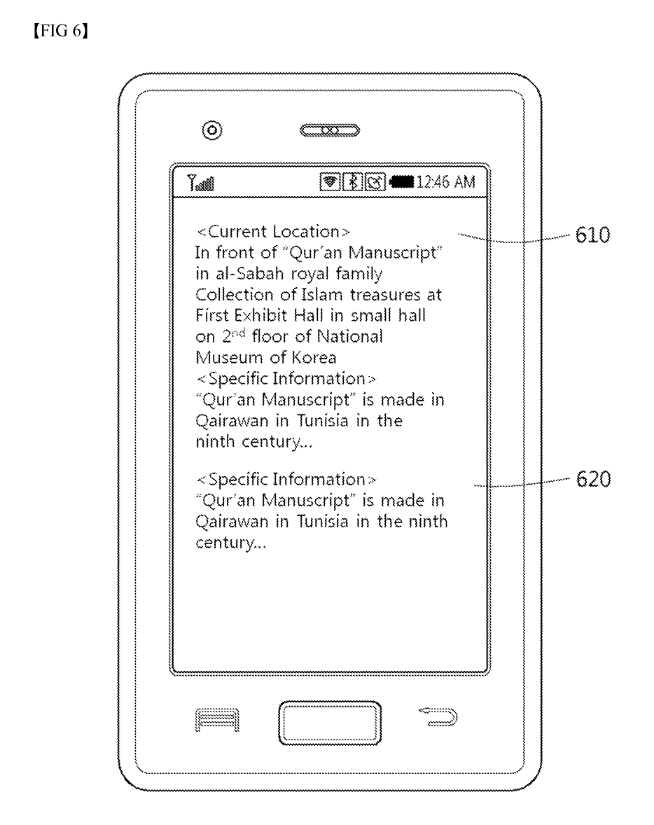

In addition, the system for constructing the map of the magnetic field may provide a specific service associated with the location of the user's terminal based on the information on the magnetic field and the map information. For example, the system for constructing the map of the magnetic field maps the magnetic field measured by the magnetic field sensor with associated magnetic field information and the map information, so as to acquire the location of the user's terminal. After that, the system for constructing the map of the magnetic field may provide a specific service through an application provided in the user's terminal based on the acquired user's terminal. At this time, the system for constructing the map of the magnetic field controls the user's terminal to download the associated magnetic field information and the map information. Accordingly, the system for constructing the map of the magnetic field may uses the associated magnetic field information and the map information in the process of providing the specific service associated with the location of the user's terminal to the user's terminal. The detailed description thereof will be disclosed, referring to FIGS. 5 and 6.

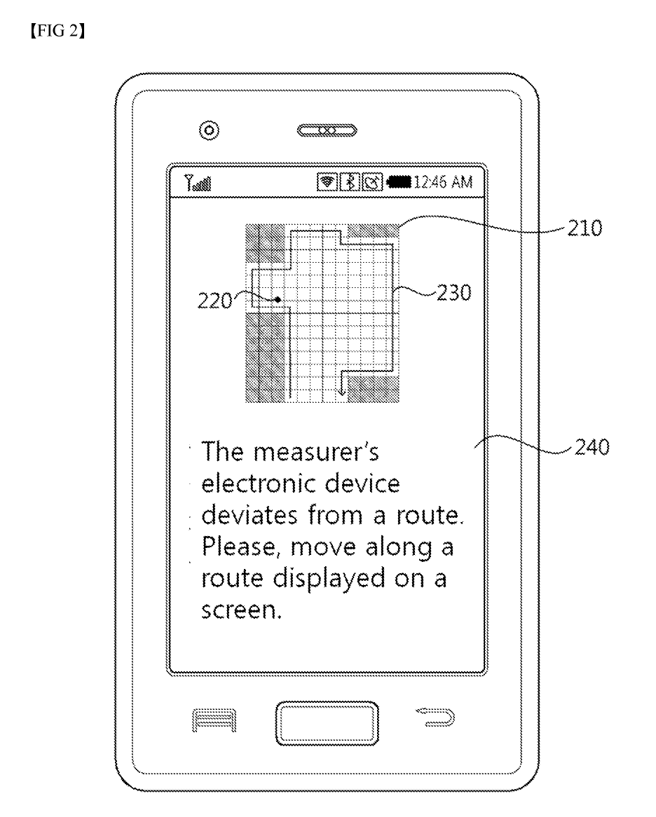

FIG. 2 is a diagram illustrating a screen of the measurer's electronic device according to the exemplary embodiments of the disclosure.

Referring to FIG. 2, the system for constructing the map of the magnetic field according to the exemplary embodiments may monitor a measuring state of the electronic device, while the measurer's electronic device is measuring the magnetic field inside or outside the building which is an object of the map constructing, such that it may provide an alarm to the electronic device based on the measuring state of the electronic device and the schedule information. The system for constructing the map of the magnetic field may provide a video alarm 210, an audio alarm or a text alarm 240 as the alarm. For example, in case the location 220 of the measurer's electronic device provided in the measuring state of the electronic device deviates from the moving path 230 provided in the schedule information, a video alarm 210 together with an audio alarm may be provided to notice that the location of the electronic device deviates from the moving route according to the schedule information. At this time, a text alarm 240 may be provided additionally.

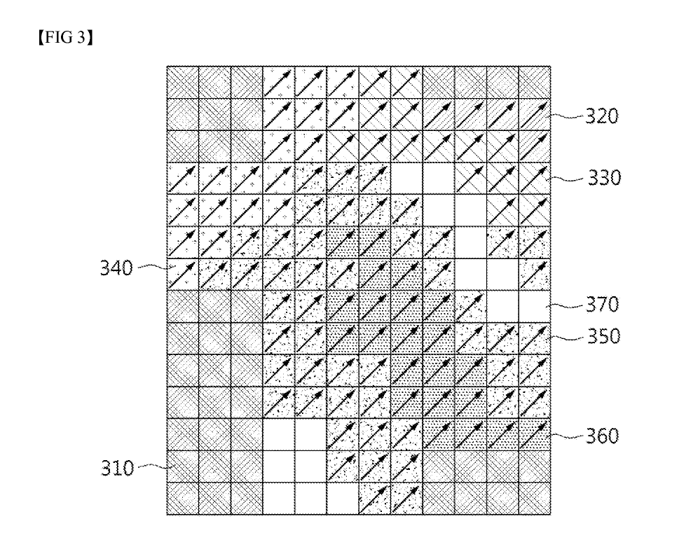

FIG. 3 is a diagram illustrating the map of the magnetic field according to the exemplary embodiments of the disclosure.

Referring to FIG. 3, the map of the magnetic field according to the exemplary embodiments of the disclosure may be constructed based on a horizontal value and a vertical value of a magnetic field measured by the electronic device corresponding to the coordinate information preset inside or outside the building according to the schedule information. For example, the map of the magnetic field may be constructed by measuring a horizontal value and a vertical value of a magnetic field corresponding to the preset coordinate information with respect to a specific reference point based on the schedule information set according to the structure information on a wall and a passage of the building.

Hereinafter, the map of the magnetic field may be constructed in consideration of only horizontal values of the magnetic field at the same heights. However, vertical values of the magnetic field may be further put into consideration.

On the map of the magnetic field, a plurality of coordinates may be displayed as a plurality of cells and information on the magnetic field may be displayed on each of the cells. For example, a cell 310 displaying information of (0, 1) coordinate may refer to an inner wall of the building and a cell 320 displaying (12, 13) coordinate information may refer to a passage where the magnetic field is measured. Specifically, shade may be displayed on a cell 310 indicating the inner wall of the building. A different shade is displayed on each of the cells indicating the passage, where the magnetic field is measured, based on the intensity of the magnetic field. Arrows indicating directions of the magnetic field may be displayed on the cells based on the intensity of the magnetic field. A cell 320 indicates the intensity of the magnetic field in a range of 0.4 Gauss or more. A cell 330 indicates the intensity of the magnetic field in a range of 0.33˜0.44 Gauss and a cell 340 indicates the intensity of the magnetic field in a range of 0.27˜0.33 Gauss. A cell 350 indicates the intensity of the magnetic field in a range of 0.2˜0.27 Gauss. A cell 360 indicates the intensity of the magnetic field in a range of 0.2 Gauss or less and a cell 370 indicates a weak intensity of the magnetic field which is not detected from the magnetic field sensor.

As mentioned above, the map of the magnetic field displays the preset coordinate information and the information on the magnetic field corresponding to the preset coordinate information, using the cells. Alternatively, the map of the magnetic field displays them, using contour lines or values.

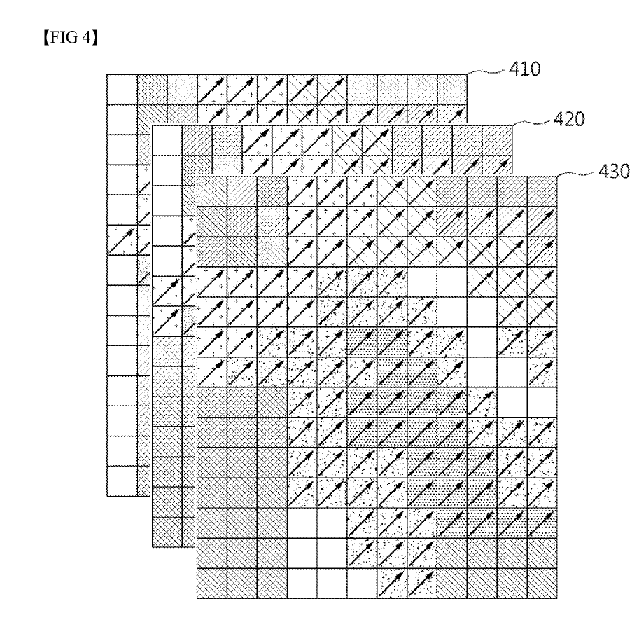

FIG. 4 is a diagram illustrating magnetic fields according to heights.

Referring to FIG. 4, maps of magnetic fields according to the exemplary embodiments of the disclosure may be generated at preset heights. Here, the preset heights may be specific heights at which horizontal values and vertical values of magnetic fields are changed at the coordinates which are horizontally identical. For example, when heights where a horizontal value and a vertical value of a magnetic field at coordinates horizontally identical are changed are 2 m and 4 m from the ground, the map of the magnetic field may include a first map of the magnetic field 410 for a height of 0˜2 m, a second map of the magnetic field for a height of 4˜6 m and a third map of the magnetic field at a height of 4˜6 m. Each map of the magnetic field may display a horizontal value and a vertical value of the magnetic field corresponding to coordinate information preset at each of the preset heights. More specifically, the first map of the magnetic field 410 may be a map of a magnetic field corresponding to a first floor in the building and the second map of the magnetic field 420 may be map of a magnetic field corresponding to a second floor in the building. The third map of the magnetic field 530 may be map of a magnetic field corresponding to a third floor in the building.

As mentioned above, maps of the magnetic field may be generated at the preset heights, respectively, and the maps may be generated as one 3D map of the magnetic field.

FIG. 5 is a diagram illustrating the process of measuring the location of the user's terminal according to the exemplary embodiments of the disclosure.

Referring to FIG. 5, the wall 510 and the user's terminal 520 may be displayed on the map for the internal structure of the building.

The system for constructing the map of the magnetic field according to the exemplary embodiments of the closure may acquire the location of the user terminal, using the map of the magnetic field constructed by associating information on the magnetic field and the map information based on the schedule information. For example, the system for constructing the map of the magnetic field maps a horizontal value and a vertical value of the magnetic field transmitted from the magnetic field sensor provided in the user terminal with the constructed map of the magnetic field, such that it may position the location of the user terminal. More specifically, when a magnetic field corresponding to information on coordinates (4, 5) on the right of the wall 510 on the map of the magnetic field may be (0.2, 0.33 and 0.54) and a magnetic field measured in the user terminal 520 is (0.2, 0.33 and 0.54), it is identified that the user terminal 520 is positioned at coordinates (4, 4) on the right of the wall 510. At this time, the magnetic field may be displayed as horizontal components including an x-component, a y-component and vertical components including a z-component.

In addition, the map for constructing the map of the magnetic field may compare a value of the magnetic field acquired by the magnetic field sensor provided in the user terminal and position the user terminal 520. At this time, the system for constructing the map of the magnetic field may use a different value acquired by another sensor distinguished from the magnetic field sensor provided in the user terminal. One or more of an acceleration sensor, an inertia sensor, a gyro sensor, a pressure sensor, a ultrasonic sensor, a temperature-humidity sensor, an infrared sensor, a Ultra-Wide Band sensor and a sensor for detecting Wi-Fi LAN or LED may be used as the distinguished sensor. For example, the system for constructing the map of the magnetic field acquired one or more of the user's stride, moving direction, moving distance and moving speed based on the value acquired by the sensor distinguished from the magnetic field sensor. Then, the system may compensate a horizontal location or a vertical location of the user terminal 520 positioned, using one or more of the acquired stride, moving direction, moving distance and moving speed. At this time, the user's stride, moving direction, moving distance or moving speed may be provided in Pedestrian Dead-Reckoning information.

A system for constructing a map of a magnetic field according to another embodiment of the disclosure is provided with an initial location of the user terminal 520 by the user terminal 520 and sets candidate locations of the user terminal based on the initial location. After that, the system for constructing the map of the magnetic field may select a location of the user terminal 520 from the set candidate locations, based on the map of the magnetic field and the value of the magnetic field measured by the magnetic field sensor. For example, when an initial location is input from the user terminal 520 is on the right of a wall 510, the system for constructing the map of the magnetic field may set candidate locations of the user terminal 520 from the initial location on the right of the wall 510 based on one or more of the user's stride, moving direction, moving distance and moving speed provided from the user terminal 520. Also, the system may select the location of the user terminal 520, using the map of the magnetic field and values of the magnetic field measured by the magnetic field.

FIG. 6 is a diagram illustrating a screen of a user terminal providing a specific service according to exemplary embodiments of the disclosure.

Referring to FIG. 6, the system for constructing the map of the magnetic field according to the exemplary embodiments of the disclosure may provide a current location 610 of the user terminal and a specific service 620 associated with a location of the user terminal based on the location of the user terminal. For example, when the user terminal is positioned on the right of the wall shown in FIG. 5, with Qur'an manuscript exhibited on the wall to the right which is one of Islamic treasures, a current location 610 of the user terminal and specific information displaying service 620 displaying specific information on “Qur'an manuscript” may be provided.

Also, the specific service may be provided in response to change in locations of the user terminal adaptively. For example, when the user terminal is moving along an upper portion of the wall from a right portion of the wall, with a port ornament exhibited on an upper portion of the wall, a changed location of the user terminal and a specific information displaying service for “port ornament” may be provided as specific information.

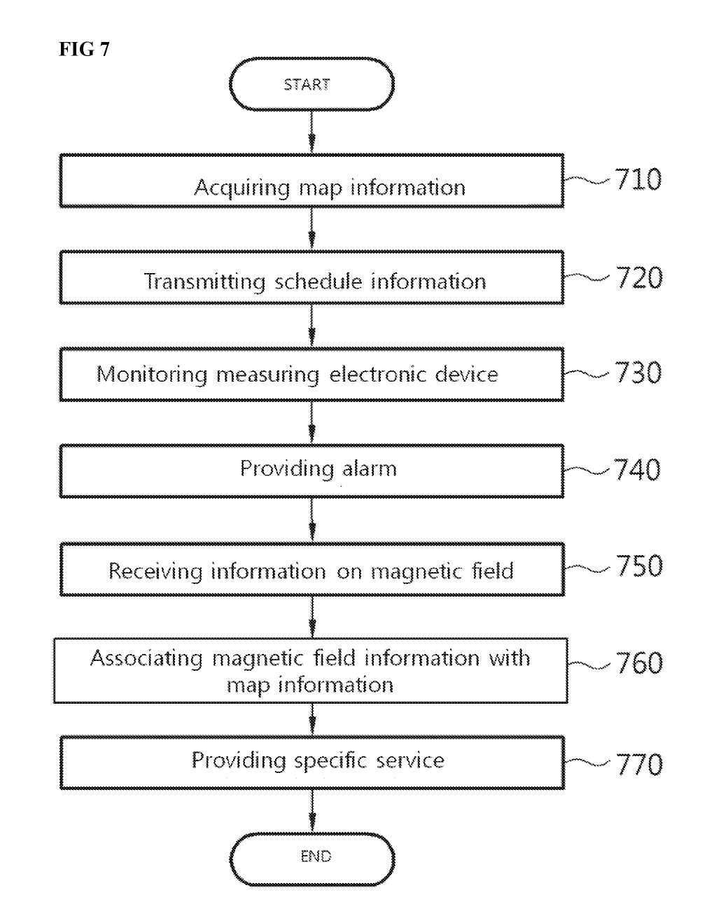

FIG. 7 is a flow chart illustrating a method for constructing a map of a magnetic field according to exemplary embodiments of the closure.

Referring to FIG. 7, the system for constructing the map of the magnetic field acquires the map information including information on an internal or external structure of a building (710).

In addition, the system for constructing the map of the magnetic field transmits the schedule information for measuring a magnetic field inside or outside the building based on the structure information (720). At this time, the schedule information may include one or more of the moving route, moving direction, moving speed and height of the measurer's electronic device.

The system for constructing the map of the magnetic field may monitor a measuring state of the measurer's electronic device, while the electronic device is measuring the magnetic field inside or outside the building (730). At this time, the electronic device may measure horizontal values and vertical values of the magnetic field corresponding to the structure information, using the magnetic sensor provided in the electronic sensor.

The system for constructing the map of the magnetic field may provide an alarm to the measurer's electronic device based on the measuring state of the electronic device and the schedule information (740).

The system for constructing the map of the magnetic field receives information on the magnetic field measured inside or outside the building from the measurer's electronic device (750).

Also, the system for constructing the map of the magnetic field associates the information on the magnetic field with the map information based on the schedule information (760), so as to construct the map of the magnetic field.

The system for constructing the map of the magnetic field may provide specific services associated with the location of the user terminal based on the information on the associated magnet field and the map information (770). At this time, the process of providing the specific services a step of acquiring the location of the user terminal by mapping the magnetic field measured by the magnetic field sensor with the information on the associated magnetic field and the map information and a step of providing specific services through applications provided in the user terminal based on the acquired location of the user terminal. Although not shown in the drawings, the system for constructing the map of the magnetic field may control the information on the associated magnetic field and the map information to be downloaded to the user terminal.

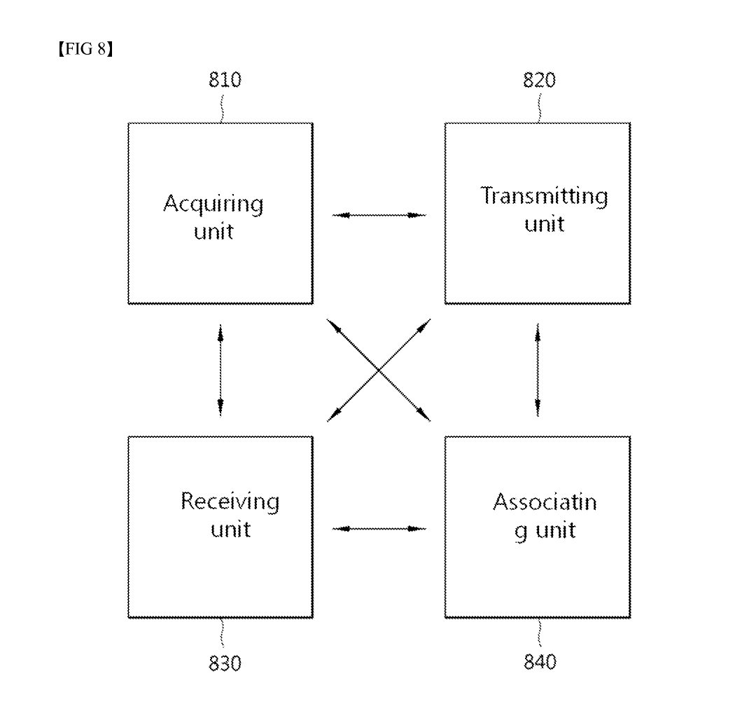

FIG. 8 is a block diagram illustrating the system for constructing the map of the magnetic field according to the exemplary embodiments of the disclosure.

Referring to FIG. 8, the system for constructing the map of the magnetic field according to the exemplary embodiments of the disclosure includes an acquiring unit 810, a transmitting unit 820, a receiving unit 830 and an associating 840.

The acquiring unit 810 acquires the map information including the information on the internal or external structure of the building.

The transmitting unit 820 transmits the schedule information for measuring a magnetic field inside or outside the building based on the structure information. At this time, the schedule information may include information on one or more of the moving route, moving direction, moving speed and height of the measurer's electronic device.

The receiving unit 830 receives information on the magnetic field measured inside or outside the building from the measurer's electronic device. At this time, the measurer's electronic device may measure a horizontal value and a vertical value of the magnetic field corresponding to the structure information, using the magnetic field sensor provided in the electronic device.

The associating unit 840 associates the information on the magnetic field with the map information based on the schedule information.

Although not shown in the drawings, the system for constructing the map of the magnetic field may further include a monitoring unit for monitoring a measuring state of the electronic device, while electronic device is measuring the magnetic field inside or outside the building, and an alarm providing unit for providing an alarm to the electronic device based on the measuring state of the electronic state and the schedule information.

Although not shown in the drawings, the system for constructing the map of the magnetic field may further include a service providing unit for providing a specific service associated with the location of the user terminal based on the information on the associated magnetic field and the map information. The service providing unit acquires the location of the user terminal by mapping the magnetic field measured by the magnetic field sensor provided in the user terminal with the information the associated magnetic fields and the map information, such that the specific service can be provided through the application installed in the user terminal based on the acquired location of the user terminal. Also, the system for constructing the map of the magnetic field may further include a downloading unit for downloading the information on the associated magnetic fields and the map information to the user terminal.

The method including steps of acquiring the map information including the information on the internal or external structure of the building; measuring the information on the magnetic field, using the measurer's electronic device; and associating the information on the magnetic field with the map information based on the schedule information or transmitting the information on the magnetic field to the system for constructing the map of the magnetic field may be performed by a processor, a memory or a communication interface provided in the electronic device.

It will be apparent to those skilled in the art that various modifications and variations can be made in the present disclosure without departing from the spirit or scope of the disclosed subject matter.

Thus, it is intended that the present disclosure cover the modifications and variations of the disclosed subject matter provided they come within the scope of the appended claims and their equivalents.

What is claimed is:

1. A method for constructing a map of a magnetic field comprising:
acquiring the map information including the information on the internal or external structure of the building;
measuring the information on the magnetic field, using the measurer's electronic device; and
associating the information on the magnetic field with the map information based on the schedule information,
wherein the schedule information is generated based on the structure information or a command made by the measurer.

2. The method of constructing the map of the magnetic field according to claim 1, wherein the schedule information comprises information on a moving route, a moving direction, a moving speed or a height from the ground of the measurer's electronic device.

3. The method of constructing the map of the magnetic field according to claim 1, wherein the measurer's electronic device measures a horizontal value and a vertical value of the magnetic field corresponding to the structure information, using a magnetic field sensor provided in the measurer's electronic device.

4. The method of constructing the map of the magnetic field according to claim 1, further comprising:
providing a specific service associated with a location of a user terminal based on the information on the associated magnetic fields and the map information.

5. The method of constructing the map of the magnetic field according to claim 4, wherein the providing the specific service comprises,
acquiring the location of the user terminal by mapping the magnetic field measured by the magnetic field sensor provided in the user terminal with the information on the associated magnetic fields and the map information; and
providing the specific service through an application installed in the user terminal based on the acquired location of the user terminal.

6. The method of constructing the map of the magnetic field according to claim 1, further comprising:
downloading the information on the associated magnetic fields and the map information to the user terminal.

7. The method of constructing the map of the magnetic field according to claim 1, further comprising:
transmitting schedule information for measuring a magnetic field inside or outside the building based on the structure information.

8. A method of constructing a map of a magnetic field comprising:
acquiring map information comprising structure information inside or outside a building;
measuring information on a magnetic field inside or outside the building, using a measurer's electronic device; and
associating the information on the magnetic field with the map information based on the schedule information or transmitting the information on the magnetic field to a system for constructing a map of a magnetic field,
wherein the schedule information is generated based on the structure information or based on the measurer's command.

9. The method of constructing the map of the magnetic field according to claim 8, further comprising:
monitoring a measuring state of the electronic device, while the measurer's electronic device is measuring the magnetic field inside or outside the building; and
providing an alarm to the measurer's electronic device based on the measuring state of the electronic device and the schedule information.

10. A system for constructing a map of a magnetic field comprising:
an acquiring unit for acquiring map information comprising information on an internal or external structure of a building;
a receiving unit for receiving information on a magnetic field measured inside or outside the building from the measurer's electronic device; and
an associating unit for associating the information on the magnetic field and the map information with each other based on the schedule information,
wherein the schedule information is generated based on the structure information or based on a command input by the measurer.
